(19) United States
(12) Patent Application Publication
(10) Pub. No.: US 2022/0077663 A1
(43) Pub. Date: Mar. 10, 2022

(54) MODULAR AND SCALABLE POWER DISTRIBUTION

(71) Applicant: Panduit Corp., Tinley Park, IL (US)

(72) Inventors: Ronald A. Nordin, Naperville, IL (US); Masud Bolouri-Saransar, Orland Park, IL (US); Surendra Chitti Babu, Naperville, IL (US)

(73) Assignee: Panduit Corp., Tinley Park, IL (US)

(21) Appl. No.: 17/465,097

(22) Filed: Sep. 2, 2021

Related U.S. Application Data
(60) Provisional application No. 63/076,430, filed on Sep. 10, 2020.

(51) Int. Cl. H02B 1/04

(52) U.S. Cl. CPC H02B 1/04

(57) ABSTRACT

A modular power distribution system includes using power extension modules and power distribution modules. The power extension modules are configured to route inputted power to another power extension module or a power distribution module. The power distribution modules are configured to route power from a power extension module to one or more racks or cabinets in a data center.

### CROSS-REFERENCE TO RELATED APPLICATION(S)

This application claims benefit to U.S. Provisional Patent Application No. 63/076,430, filed on Sep. 10, 2020, the entirety of which is hereby incorporated by reference herein.

### FIELD OF THE INVENTION

The present invention relates generally to power distribution systems and more specifically a modular power distribution system that combines the best features of a power bus system and a point-to-point wiring system.

### BACKGROUND

The power from the electric utility must be distributed efficiently to IT equipment contained within cabinets in data centers (or in enterprise or industrial settings). This power is typically distributed in 3-phase Delta or Wye configurations to each of the cabinets. The power is than connected to the cabinet's rack-PDU (Power Distribution Unit) where the power is distributed to each of the IT equipment. Today's methods of distributing this power are designed specifically for the particular application.

As shown in FIG. 1, power first enters a facility from the electric utility at a high voltage level (typically 35 kV), where it is first stepped down to a low voltage (e.g., 480 VAC) and routed to a main switch gear. Here a selection between the utility power or a backup generator is selected. After the switch gear, the power is typically stepped down again to either 415 or 208 prior to or within the distribution cabinets. The distribution cabinets than route power to each of the PDU's where it is further distributed to the cabinets containing IT equipment.

Once the power is routed to the Data Hall's PDU, traditionally it has been distributed to the cabinets containing IT equipment by either point to point wiring or through a power bus method. FIG. 2A shows a block diagram of a power bus method of distributing power to each cabinet's rack-based PDU. Power bus systems are typically routed above the cabinets only. The rack-based PDU(s) connects to a “tap-off-point” box that is connected to the power bus. These tap-off-points are required to contain a breaker and optionally can have a power measurement capability. Some of the drawbacks of a power bus system is the material cost of the equipment, the installation cost, and the consultative services required to design the power distribution system.

FIG. 2B shows a block diagram of a point-to-point wiring power distribution system. Power cables run from each of the rack-based PDUs to either a power distribution cabinet or a remote power panel. The point-to-point wiring can be either overhead or under floor (as shown). Some of the drawbacks of a point-to-point wiring method of power distribution include initial installation cost and the cost of making changes to the system.

### SUMMARY

A modular power distribution system includes using power extension modules and power distribution modules. The power extension modules are configured to route inputted power to another power extension module or a power distribution module. The power distribution modules are configured to route power from a power extension module to one or more racks or cabinets in a data center. In one embodiment, the modular power distribution system can also include power feed modules and/or breaker modules.

### BRIEF DESCRIPTION OF THE FIGURES

FIG. 1 shows a block diagram on how power is distributed in a data center.

FIG. 2A shows how power is distributed to cabinets using a Power Bus system.

FIG. 2B shows how power is distributed to cabinets using point-to-point wiring.

FIG. 3A shows a modular power distribution system according to the present invention.

FIG. 3B shows the power distribution panel for the system of FIG. 3A.

FIG. 3C shows the power distribution and power extension modules for the system of FIG. 3A.

FIG. 4A shows the power distribution module wiring.

FIG. 4B shows the power extension module wiring.

FIG. 5A shows the breaker module.

FIG. 5B shows the power feed module.

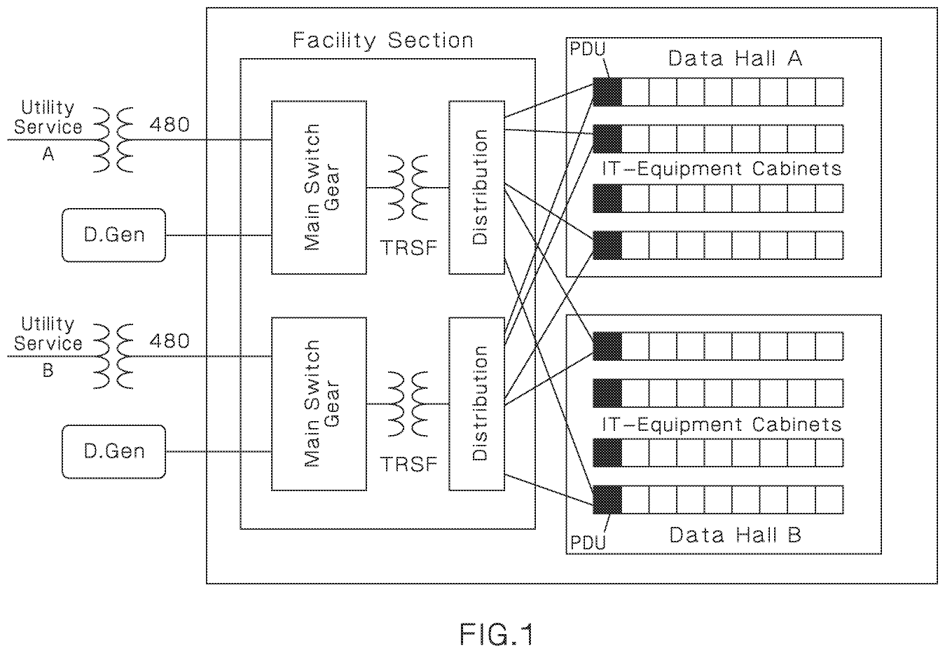

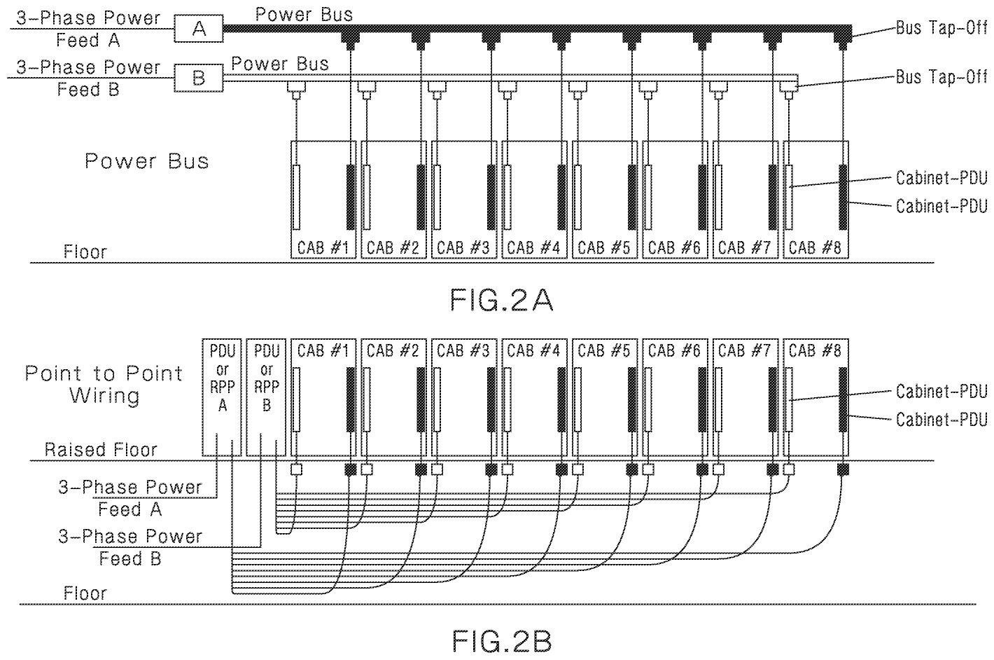

### DETAILED DESCRIPTION OF THE INVENTION

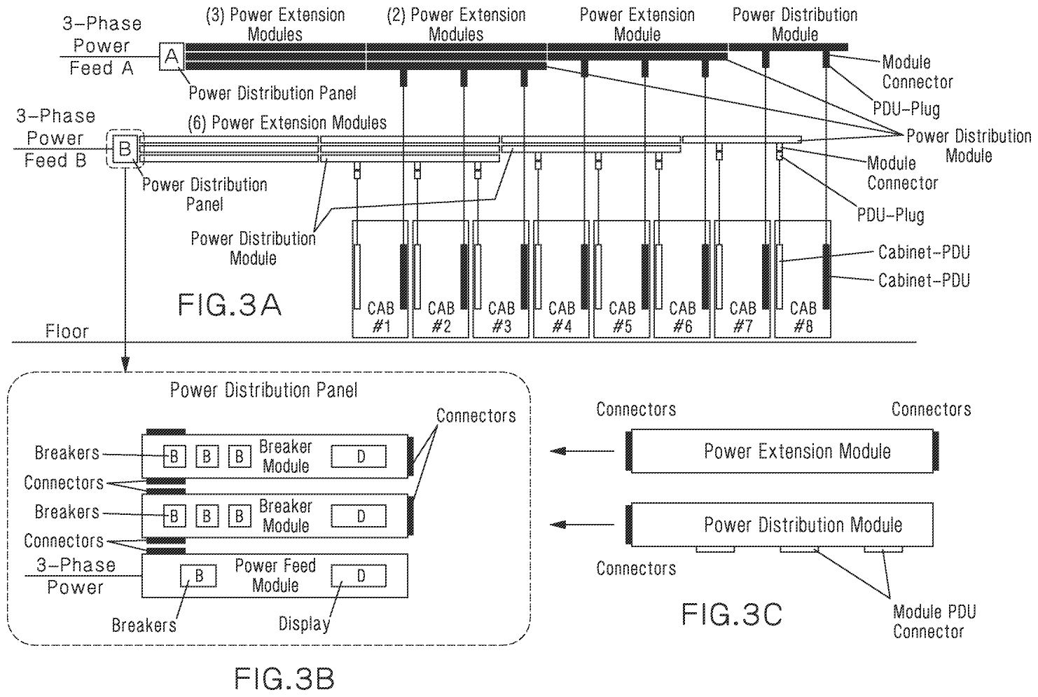

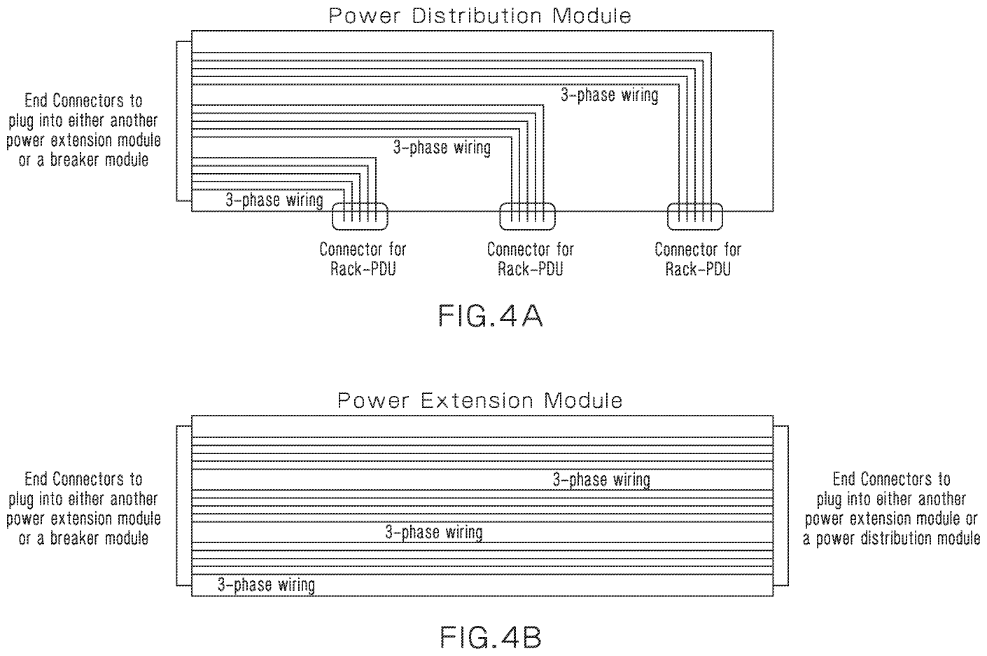

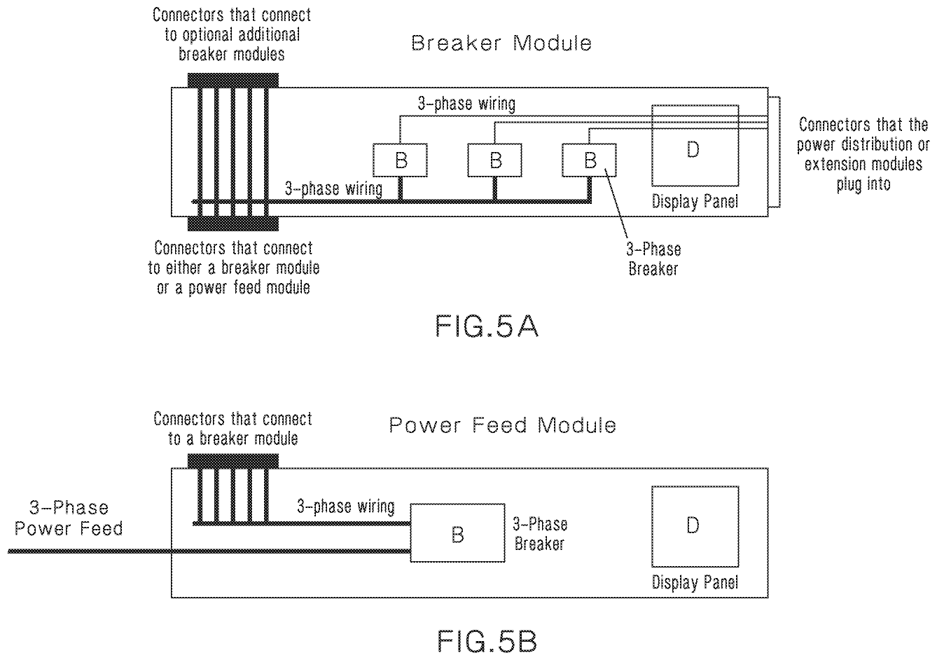

A novel technique of distributing power is shown in FIG. 3A. This technique combines the best features of the power bus method and the best features of point-to-point wiring method. This technique offers a modular and scalable solution for the distribution of power. Each of the rack-based PDUs plug into a power distribution module. The power distribution module is equipped with outlets where a multiple of rack-PDUs can plug into (a preferred number is three or four). Additionally, the power distribution module can contain branch circuit power monitoring circuitry. The power extension modules do not have any outlets and its primary purpose is serve as interface between the breaker module and power distribution module. Additionally, the power extension modules can transport the branch circuit monitoring information form the power distribution modules back to the power feed panel. The power distribution module connects to as many of the power extension modules as necessary to transfer power from the power distribution panel back to the power feed panel (see FIG. 3A). These power distribution and extension modules are connectorized at the ends to plug into one another as well as plugging into the breaker module within the power distribution panel (see FIG. 3C and further shown in FIGS. 4A and 4B). The power distribution panel is shown in FIG. 3B and further shown in FIGS. 5A and 5B. It is a modular and scalable system composing of two modules: the power feed module and the breaker module. The power feed module connects to the main power feed cable (typically a 3-phase Delta or Wye configuration) and to the breaker modules. The power feed module can contain a high-power breaker for the main power feed (and optionally a display panel to indicate the power levels being drawn from the main power feed). The breaker modules can tap into the power from the power feed module and connect to other breaker modules and either the power distribution or extension modules. The breaker module contains a current breaker for each of the power lines connecting to the rack-based PDUs (three 3-phase breakers are shown in FIG. 3C) and an optional display panel to indicate the power levels in each rack-PDU that it is connected to. Note the function of the breaker module can be integrated into the power distribution modules and the extension modules.

The advantages of this power distribution method are:
Lower part cost and simpler design
A lower cost of installation
Ease of installation and ease of scalability to larger systems
No consultative services required for the system design.

The technique provides the flexibility, scalability, and modularity of a Power Bus system at the cost of a point-to-point system.

FIGS. 4A and 4B describe the wiring for both the power distribution and extension modules. FIG. 4A shows the wiring diagram for the power distribution module which connects the end connector to each of the PDU connectors. FIG. 4B shows the wiring diagram for the power extension module which connects the two end connectors together.

1. A modular system for the distribution of power comprising:
a power extension module configured to route inputted power to one of a second power extension module or a power distribution module; and
a power distribution module configured to route power from a power extension module to a rack or cabinet.

2. The modular system of claim 1 further comprising a power feed module.

3. The modular system of claim 2 further comprising a breaker module.
